(19) United States
(12) Patent Application Publication
(10) Pub. No.: US 2007/0146082 A1
(43) Pub. Date: Jun. 28, 2007

(54) Frequency synthesizer, wireless communications device, and control method

(76) Inventors: Atsushi Ohara, Shiga (JP); Takayuki Tsukizawa, Osaka (JP)

Correspondence Address: MCDERMOTT WILL & EMERY LLP, 600 13TH STREET, N.W., WASHINGTON, DC, 20005-3096, US

(21) Appl. No.: 11/635,084

(22) Filed: Dec. 7, 2006

(30) Foreign Application Priority Data
Dec. 7, 2005 (JP) 2005-353084

(51) Int. Cl. H03L 7/00

(52) U.S. Cl. 331/16

(57) ABSTRACT

A plurality of control voltages V1 to V3 are sequentially applied to a VCO 5 so as to obtain, for each of these control voltages, the operating reference voltages Vref1 to Vref3 for the variable capacitor elements VC51 to VC56 with which the difference between the oscillation frequency of the VCO 5 and the target frequency is minimum. With this operation, the frequency synthesizer of the present invention can not only set the oscillation frequency of the VCO 5 for a single control voltage to a desirable value but also set the control sensitivity at the oscillation frequency of the VCO 5 with varied control voltage to a desirable value.

### BACKGROUND OF THE INVENTION

1. Field of the Invention

The present invention relates to a frequency synthesizer for use in a semiconductor integrated circuit, a wireless communications device using the same, and a method for controlling the same.

2. Description of the Background Art

Conventional frequency synthesizers in semiconductor integrated circuits for use in the field of mobile communications, or the like, employ a configuration using the resonant frequency obtained by an inductor and a variable capacitor in order to ensure high-frequency operation and phase noise performance. In order to stabilize the response characteristic and the phase noise characteristic of frequency synthesizers over a wide range and to stabilize the modulation sensitivity thereof when used as a modulator, measures have been taken to improve the linearity of voltage controlled oscillator sections used in frequency synthesizers. See, for example, Japanese Laid-Open Patent Publication No. 2004-147310 (Patent Document 1) and Japanese Laid-Open Patent Publication No. 2001-352218 (Patent Document 2).

FIG. 14 shows a circuit configuration of a conventional frequency synthesizer using a voltage controlled oscillator section with improved linearity. Referring to FIG. 14, the conventional frequency synthesizer includes a reference signal generating section 501, a phase/frequency comparing section 502, a charge pump section 503, a loop filter section 504, a voltage controlled oscillator section (VCO) 505, a frequency divider section 506, an operating reference voltage control section 509, a frequency division ratio control section 511, and a serial decoder/latch section 512.

The reference signal generating section 501 produces a reference signal having a frequency based on which the operating frequency is set for the frequency synthesizer. The phase/frequency comparing section 502 compares the frequency and the phase of the reference signal outputted from the reference signal generating section 501 with those of the frequency-divided signal outputted from the frequency divider section 506 to produce an error signal based on the result of the comparison. The charge pump section 503 converts the error signal produced by the phase/frequency comparing section 502 to an appropriate voltage. The loop filter section 504 filters the voltage from the charge pump section 503 with an appropriate loop band. The frequency divider section 506 divides the frequency of the oscillating signal from the VCO 505 under the control of the frequency division ratio control section 511, and outputs the obtained signal to the phase/frequency comparing section 502.

The VCO 505 includes inductors L551 and L552, a variable capacitor section 551, transistors M551 and M552, and a current source 1551. The oscillation frequency of the VCO 505 is determined by the inductors L551 and L552 and the total capacitance of the variable capacitor section 551. The variable capacitor section 551 includes variable capacitor elements VC551 to VC556 whose capacitance values vary according to the voltage applied between opposite ends thereof, capacitors C551 to C556 connected to one end of the variable capacitor elements VC551 to VC556 for blocking the direct current component, and bias resistors R551 to R556 for transmitting the operating reference voltages for the variable capacitor elements VC551 to VC556. The variable capacitor elements VC551 and VC552 determine the oscillation frequency characteristic in the upper limit region of the input voltage Vt, the variable capacitor elements VC555 and VC556 determine that in the lower limit region of the input voltage Vt, and the variable capacitor elements VC553 and VC554 determine that in the intermediate region of the input voltage Vt. The operating reference voltage control section 509 outputs the operating reference voltage Vref1 for the variable capacitor elements VC551 and VC552, the operating reference voltage Vref2 for the variable capacitor elements VC555 and VC556, and the operating reference voltage Vref3 for the variable capacitor elements VC553 and VC554. The serial decoder/latch section 512 receives from outside a serial input signal containing information such as the frequency (frequency division ratio) and whether the frequency synthesizer is ON/OFF, decodes and latches the serial input signal, and outputs the signal to the frequency division ratio control section 511. The frequency division ratio control section 511 controls the frequency division ratio of the frequency divider section 506.

How the oscillation frequency of the VCO 505 changes with respect to the input voltage Vt and the operating reference voltage Vref will now be discussed with reference to FIGS. 15A to 15D.

In FIG. 15A, the horizontal axis represents the potential difference Vt-Vref between the input voltage Vt and the operating reference voltage Vref of the VCO 505, and the vertical axis represents the oscillation frequency fvco of the VCO 505. Consider a typical control characteristic example of a pair of variable capacitor elements for the sake of simplicity. The VCO 505 has a characteristic such that the frequency is higher when Vt−Vref<0 and lower when Vt−Vref>0, with respect to the frequency when Vt−Vref=0.

Now refer to FIG. 15B, where the horizontal axis represents the input voltage Vt of the VCO 505 and the vertical axis represents the oscillation frequency fvco of the VCO 505 with respect to the operating reference voltage Vref. With such a control characteristic as described above, the variable region of the input voltage Vt is moved higher (dotted line) when the operating reference voltage Vref is increased, and lower (one-dot chain line) when the operating reference voltage Vref is decreased.

Such a characteristic can be taken advantage of as follows. Where a plurality of variable capacitor elements of different operating reference voltages are used, the control characteristics of the variable capacitor elements will have narrow variable regions centered at Vt=Vref1 to Vref3 as shown in thin solid lines G1 to G3 in FIG. 15C. With these variable capacitor elements combined together, it is possible to realize a wide variable region of the frequency fvco with respect to the control voltage Vt as shown in a thick solid line G10 in FIG. 15C. The linearity of the VCO 505 can be improved as described above.

However, with the conventional frequency synthesizer of Patent Document 1 shown in FIG. 14, how the frequency changes in response to a change in the input voltage Vt of the VCO 505, i.e., the control sensitivity (or the modulation sensitivity where the frequency synthesizer is used as a modulator) is varied by variations in the characteristics of devices used in the circuit, the temperature variations, or the power supply voltage variations. While the conventional frequency synthesizer provides the advantageous effect of expanding the linear region while lowering the sensitivity as shown in FIG. 15C, the sensitivity may become too low or too high, as shown in dotted lines in FIG. 15D, relative to the desired sensitivity shown in a solid line in FIG. 15D, due to variations.

Patent Document 2 proposes a circuit using frequency correction. However, the problem is that by simply correcting the frequency, the sensitivity will still vary. Moreover, while Patent Document 2 can correct an offset in the output frequency, the control sensitivity and the modulation sensitivity at that time will vary. Moreover, Patent Document 2 uses small-sized variable capacitor elements for modulation, with the size thereof being reduced to 1/100, for example, in an attempt to obtain desirable sensitivity. However, with oscillators of high frequencies, particularly, those of over 1 GHz, the parasitic capacitance Cj of the oscillating MOS transistor and the wiring will have increased influence on the oscillation frequency f, which is no longer negligible with respect to the capacitance value Co of the variable capacitor element. Specifically, f=1/(2 πL(Co+Cj)/2), whereby even if the capacitance value Co of the variable capacitor element, which determines the reference frequency, is reduced to 1/100, the sensitivity will not become accurately 1/100.

### SUMMARY OF THE INVENTION

Therefore, an object of the present invention is to provide a frequency synthesizer, a wireless communications device and a control method, in which the control sensitivity or the modulation sensitivity are not influenced by variations in the production process, temperature variations, variations in the power supply voltage, or the like, while ensuring the frequency correction function in the prior art as proposed in Patent Document 2, and the like.

The present invention is directed to a frequency synthesizer for use in a semiconductor integrated circuit, and a wireless communications device using the same. In order to achieve the object set forth above, a frequency synthesizer of the present invention includes a voltage controlled oscillator section (VCO), a frequency divider section, a voltage producing section, a control voltage switching section, a frequency detection section, an operating reference voltage control section, and a timing control section.

The voltage controlled oscillator section is a section including a variable capacitor section including a plurality of variable capacitor elements whose capacitance values vary according to a control voltage applied between opposite ends thereof, for outputting a signal of an oscillation frequency based on the control voltage and a plurality of predetermined operating reference voltages. The frequency divider section is a section for dividing a frequency of a signal outputted from the voltage controlled oscillator section with a predetermined frequency division ratio. The voltage producing section is a section for comparing the frequency-divided signal from the frequency divider section with a predetermined reference signal so as to produce a voltage for performing a feedback control of an oscillation frequency of the voltage controlled oscillator section based on a result of the comparison. The control voltage switching section is a section for receiving the voltage produced by the voltage producing section and a plurality of fixed voltages of different values so as to selectively output one of the received voltages to the voltage controlled oscillator section as the control voltage. The frequency detection section is a section for comparing a frequency of the frequency-divided signal from the frequency divider section with the frequency of the predetermined reference signal so as to produce an error signal based on a result of the comparison. The operating reference voltage control section is a section for varying each of a plurality of operating reference voltages to be supplied to the plurality of variable capacitor elements according to the error signal produced by the frequency detection section. The timing control section is a section for specifying a voltage to be selected in the control voltage switching section, controlling switching operation timing of the control voltage switching section, controlling operation timing of the frequency detection section, specifying an operating reference voltage to be varied by the operating reference voltage control section, and controlling operation timing of the operating reference voltage control section.

In one embodiment of the present invention, the operating reference voltage control section includes a plurality of resistors inserted in a serial arrangement between any two of the operating reference voltages; and a voltage obtained through voltage division by means of the plurality of resistors is supplied to the plurality of variable capacitor elements as at least one of the operating reference voltages. In one embodiment of the present invention, the voltage controlled oscillator section includes a fixed capacitance value switching section for switching between capacitance values of the voltage controlled oscillator section by adding a fixed capacitance to the variable capacitor section; and the frequency synthesizer further includes a fixed capacitance value control section for controlling the fixed capacitance value added to the variable capacitor section by the fixed capacitance value switching section under a control by the timing control section.

There may be two variable capacitor sections provided in the voltage controlled oscillator section. In such a case, there may be provided a first control voltage switching section for switching the control voltage for the first variable capacitor section, and a second control voltage switching section for switching the control voltage for the second variable capacitor section.

The frequency synthesizer having such a configuration may employ a method including the steps of: applying one of a plurality of control voltages of different values to the variable capacitor element, the applied control voltage being selected sequentially in a predetermined order from among the plurality of control voltages; for a first control voltage of the plurality of control voltages, adjusting a corresponding operating reference voltage so that a frequency of the output signal of the frequency synthesizer becomes equal to a first target frequency predetermined for the first control voltage; and after adjusting the operating reference voltage for the first control voltage, adjusting, for at least one of a plurality of control voltages other than the first control voltage, a corresponding operating reference voltage so that the frequency of the output signal of the frequency synthesizer becomes equal to a target frequency predetermined for the at least one control voltage. Thus, it is possible to perform an accurate PLL operation.

Typically, the method includes the steps of: setting the control voltage to a first value and detecting a frequency of the output signal of the frequency synthesizer at that point in time as a first frequency; varying a first operating reference voltage so that a desired frequency is obtained; setting the control voltage to a second value after adjusting the first operating reference voltage and detecting a frequency of the output signal of the frequency synthesizer at that point in time as a second frequency; varying a second operating reference voltage so that a desired frequency is obtained; and adjusting the first operating reference voltage to correct how the first frequency changes when the second operating reference voltage is varied. Where fixed capacitance values are switched from one to another, the switching between fixed capacitance values may be adjusted for the first control voltage so that the frequency of the output signal of the frequency synthesizer becomes equal to a first target frequency predetermined for the first control voltage.

As described above, according to the present invention, it is possible to realize a frequency synthesizer in which the control sensitivity or the modulation sensitivity is not influenced by variations in the production process, temperature variations, variations in the power supply voltage, or the like, while ensuring the frequency correction function in the prior art as proposed in Patent Document 2, and the like.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a circuit configuration of a frequency synthesizer according to a first embodiment of the present invention.

FIGS. 2A and 2B are timing diagrams each showing an operation of the frequency synthesizer according to the first embodiment of the present invention.

FIGS. 3A and 3B each show control voltage-oscillation frequency characteristic of a VCO 5 of FIG. 1.

FIG. 4 shows a circuit configuration of a frequency synthesizer according to a second embodiment of the present invention.

FIG. 5 shows a circuit configuration of a frequency synthesizer according to a third embodiment of the present invention.

FIGS. 6A and 6B show control voltage-oscillation frequency characteristic of a VCO 35 of FIG. 5.

FIG. 7 is a timing diagram showing the operation of the frequency synthesizer according to the third embodiment of the present invention.

FIG. 8 shows a circuit configuration of a frequency synthesizer according to a variation of the third embodiment of the present invention.

FIG. 9 is a timing diagram showing the operation of the frequency synthesizer according to a variation of the third embodiment of the present invention.

FIG. 10 shows a circuit configuration of a frequency synthesizer according to a fourth embodiment of the present invention.

FIG. 11 is a timing diagram showing the operation of the frequency synthesizer according to the fourth embodiment of the present invention.

FIG. 12 shows an exemplary circuit configuration of a wireless communications device 100 using a frequency synthesizer according to the first to fourth embodiments of the present invention.

FIG. 13 shows an exemplary circuit configuration of a wireless communications device 200 using a frequency synthesizer according to the first to fourth embodiments of the present invention.

FIG. 14 shows a circuit configuration of a conventional frequency synthesizer.

FIGS. 15A to 15D show the control voltage-oscillation frequency characteristic of a VCO 505 of FIG. 14.

### DESCRIPTION OF THE PREFERRED EMBODIMENTS

### First Embodiment

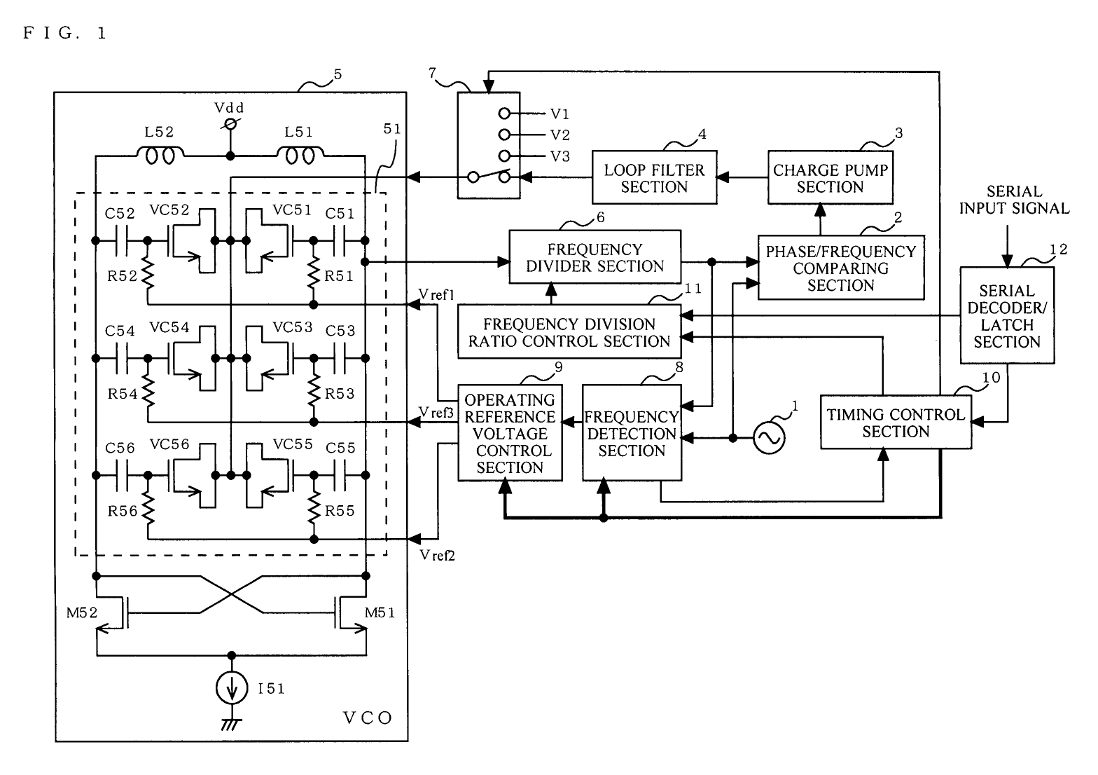

FIG. 1 shows a circuit configuration of a frequency synthesizer according to a first embodiment of the present invention. Referring to FIG. 1, the frequency synthesizer of the first embodiment includes a reference signal generating section 1, a phase/frequency comparing section 2, a charge pump section 3, a loop filter section 4, a voltage controlled oscillator section (VCO) 5, a frequency divider section 6, a control voltage switching section 7, a frequency detection section 8, an operating reference voltage control section 9, a timing control section 10, a frequency division ratio control section 11, and a serial decoder/latch section 12.

The reference signal generating section 1 produces a reference signal having a frequency fref based on which the operating frequency is set for the frequency synthesizer. The phase/frequency comparing section 2 compares the frequency and the phase of the reference signal outputted from the reference signal generating section 1 with those of the frequency-divided signal outputted from the frequency divider section 6 to produce an error signal based on the result of the comparison. The charge pump section 3 converts the error signal produced by the phase/frequency comparing section 2 to an appropriate voltage. The loop filter section 4 filters the voltage from the charge pump section 3 with an appropriate loop band. The control voltage switching section 7 receives the voltage outputted from the loop filter section 4 and a plurality of voltages (V1 to V3 in the example shown in FIG. 1), and selectively outputs one of the input voltages as the control voltage. The VCO 5 receives the control voltage selected by the control voltage switching section 7, and produces an oscillating signal of a frequency that is controlled by the control voltage. The frequency divider section 6 divides the frequency of the signal outputted from the VCO 5 under the control of the frequency division ratio control section 11, and outputs the obtained signal to the phase/frequency comparing section 2. Thus, the reference signal generating section 1, the phase/frequency comparing section 2, the charge pump section 3 and the loop filter section 4 together function as a voltage producing section for producing a voltage used in a feedback control of the oscillation frequency of the VCO 5.

The VCO 5 includes inductors L51 and L52, a variable capacitor section 51, transistors M51 and M52, and a current source I51. The oscillation frequency of the VCO 5 is determined by the inductors L51 and L52 and the total capacitance of the variable capacitor section 51. The variable capacitor section 51 includes variable capacitor elements VC51 to VC56 whose capacitance values vary according to the voltage applied between opposite ends thereof, capacitors C51 to C56 connected to one end of the variable capacitor elements VC51 to VC56 for blocking the direct current component, and bias resistors R51 to R56 for transmitting the operating reference voltages for the variable capacitor elements VC51 to VC56. The variable capacitor elements VC51 and VC52 determine the oscillation frequency characteristic in the upper limit region of the input voltage Vt, the variable capacitor elements VC55 and VC56 determine that in the lower limit region of the input voltage Vt, and the variable capacitor elements VC53 and VC54 determine that in the intermediate region of the input voltage Vt.

The timing control section 10 receives a switching signal such as a transmission/reception switching signal to thereby control the operation of the frequency detection section 8 and the switching timing of the control voltage switching section 7. The frequency detection section 8 compares the frequency fref of the reference signal outputted from the reference signal generating section 1 with that of the frequency-divided signal outputted from the frequency divider section 6 to produce an error signal based on the result of the comparison and output the error signal to the operating reference voltage control section 9. The operating reference voltage control section 9 receives the error signal produced by the frequency detection section 8, and outputs the operating reference voltage Vref1 for the variable capacitor elements VC51 and VC52, the operating reference voltage Vref2 for the variable capacitor elements VC55 and VC56, and the operating reference voltage Vref3 for the variable capacitor elements VC53 and VC54.

The serial decoder/latch section 12 receives from outside a serial input signal containing information such as the frequency (frequency division ratio) and whether the frequency synthesizer is ON/OFF, decodes and latches the serial input signal, and outputs the signal to the timing control section 10 and the frequency division ratio control section 11. The timing control section 10 controls the switching timing of the control voltage switching section 7, and the operation timing of the frequency detection section 8 and the operating reference voltage control section 9. The frequency division ratio control section 11 controls the frequency division ratio of the frequency divider section 6. Note that in the figure, a control signal and a set of control signals are both represented by a single thick line.

The operation of the frequency synthesizer of the first embodiment having such a configuration will now be described. The frequency synthesizer of the first embodiment is characteristic in that the frequency synthesizer sequentially applies a plurality of control voltages V1 to V3 to the VCO 5 so as to obtain, for each of these control voltages, the operating reference voltages Vref1 to Vref3 for the variable capacitor elements VC51 to VC56 with which the error between the oscillation frequency of the VCO 5 and the target frequency is minimum. With this operation, the frequency synthesizer of the first embodiment can not only set the oscillation frequency of the VCO 5 for a single control voltage to a desirable value but also set the control sensitivity at the oscillation frequency of the VCO 5 with varied control voltage to a desirable value.

Consider a case where a serial input signal for transitioning the frequency synthesizer from OFF to ON is given to the serial decoder/latch section 12.

First, the timing control section 10 is notified by the serial decoder/latch section 12 of the information to turn ON the operation of the frequency synthesizer. In response to the notification, the timing control section 10 controls the control voltage switching section 7 so that the control voltage V1 is inputted to the VCO 5. Where fvco1 is the target value of the oscillation frequency fvco of the VCO 5 when the control voltage V1 is inputted, the frequency divider section 6 is controlled by the frequency division ratio control section 11 so that the frequency division ratio M1 becomes M1=fvco1/fref. The frequency detection section 8 compares the frequency of the frequency-divided signal outputted from the frequency divider section 6 with that of the reference signal outputted from the reference signal generating section 1, and changes the operating reference voltage Vref1 of the VCO 5 so that the frequency of the frequency-divided signal outputted from the frequency divider section 6 becomes fvco/M1=fref, i.e., so that the frequency of the VCO 5 becomes fvco=fref×M1=fvco1.

When the frequency of the VCO 5 becomes equal to the target value fvco1, the operating reference voltage Vref1 at that time is fixed, and the timing control section 10 next controls the control voltage switching section 7 so that the control voltage V2 is inputted to the VCO 5. Where fvco2 is the target value of the oscillation frequency fvco of the VCO 5 when the control voltage V2 is inputted, the frequency divider section 6 is controlled by the frequency division ratio control section 11 so that the frequency division ratio M2 becomes M2=fvco2/fref. The frequency detection section 8 compares the frequency of the frequency-divided signal outputted from the frequency divider section 6 with that of the reference signal outputted from the reference signal generating section 1, and changes the operating reference voltage Vref2 of the VCO 5 so that the frequency of the frequency-divided signal outputted from the frequency divider section 6 becomes fvco/M2=fref, i.e., so that the frequency of the VCO 5 becomes fvco=fref×M2=fvco2.

When the frequency of the VCO 5 becomes equal to the target value fvco2, the operating reference voltage Vref2 at that time is fixed, and the timing control section 10 next controls the control voltage switching section 7 so that the control voltage V3 is inputted to the VCO 5. Where fvco3 is the target value of the oscillation frequency fvco of the VCO 5 when the control voltage V3 is inputted, the frequency divider section 6 is controlled by the frequency division ratio control section 11 so that the frequency division ratio M3 becomes M3=fvco3/fref. The frequency detection section 8 compares the frequency of the frequency-divided signal outputted from the frequency divider section 6 with that of the reference signal outputted from the reference signal generating section 1, and changes the operating reference voltage Vref3 of the VCO 5 so that the frequency of the frequency-divided signal outputted from the frequency divider section 6 becomes fvco/M3=fref, i.e., so that the frequency of the VCO 5 becomes fvco=fref×M3=fvco3.

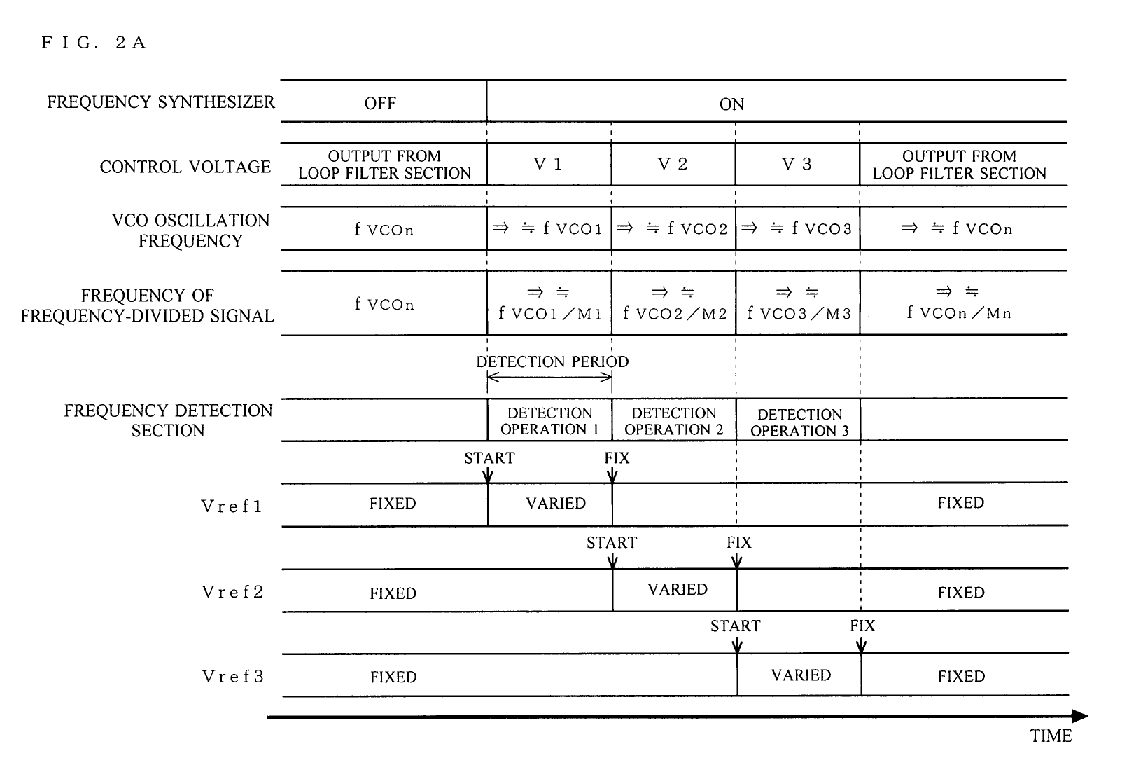

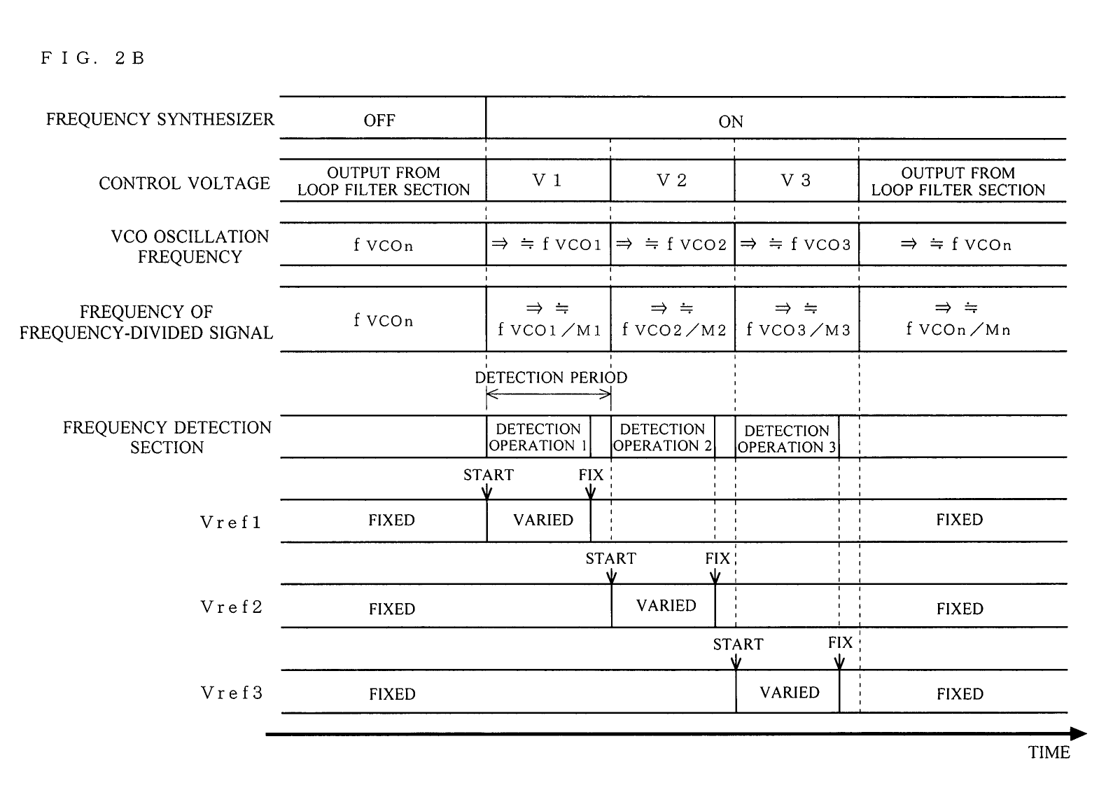

FIGS. 2A and 2B are timing diagrams each showing an operation of the frequency synthesizer of the first embodiment. FIG. 2A shows an operation where there is a certain detection period for performing a detection operation, and the operating reference voltage being outputted upon completion of the detection period is fixed as the voltage to be set. FIG. 2B shows an operation where the operating reference voltage being outputted when the operating reference voltage is determined to have converged is fixed as the voltage to be set, irrespective of the detection period.

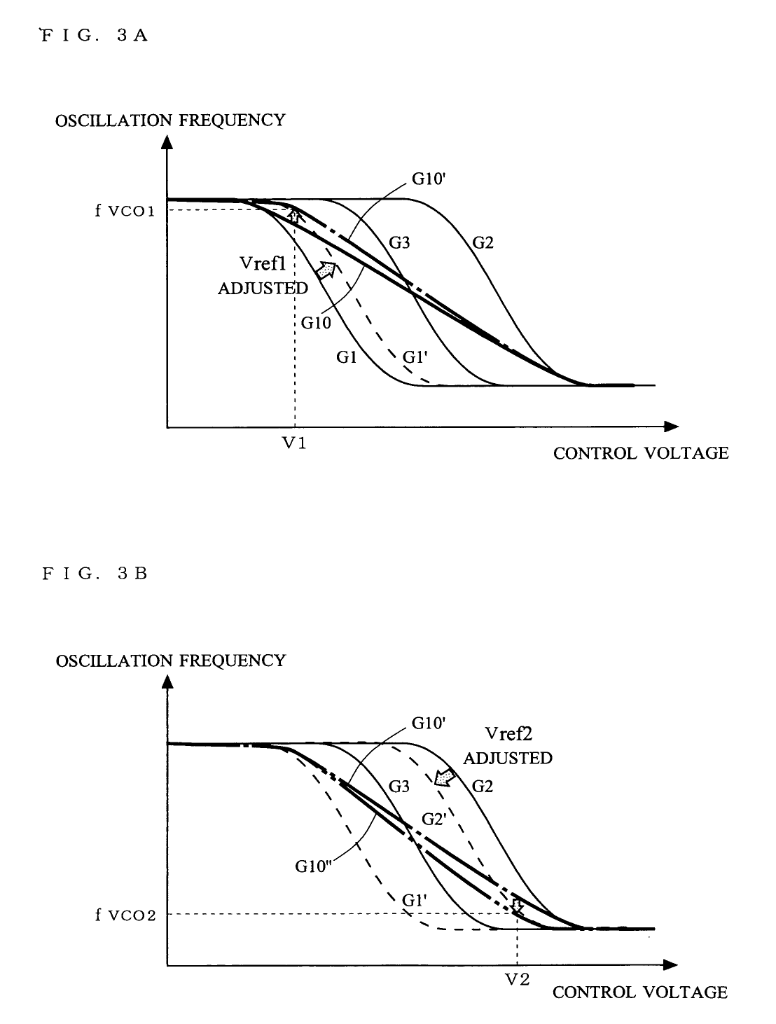

FIGS. 3A and 3B each show an example of a method for controlling the frequency synthesizer of the first embodiment. FIGS. 3A and 3B each show the control voltage-oscillation frequency characteristic of the VCO 5.

In FIG. 3A, the control voltage-oscillation frequency characteristics for the three pairs of the variable capacitor elements, i.e., VC51-VC52, VC55-VC56 and VC53-VC54 at an initial state, are denoted by solid lines G1 to G3, respectively, and the overall characteristic for these pairs is denoted by a thick solid line G10. First, when the control voltage V1 is being selected, the operating reference voltage control section 9 adjusts the operating reference voltage Vref1 so that the frequency of the frequency-divided signal outputted from the frequency divider section 6 becomes equal to the target frequency fvco1. Then, the oscillation frequency characteristic G1 changes to G1′ (dotted line), whereby the overall characteristic G10 changes to G10′ (one-dot chain line). Therefore, the frequency of G10′ for the control voltage V1 is fvco1. Next, referring to FIG. 3B, when the control voltage V2 is being selected, the operating reference voltage control section 9 adjusts the operating reference voltage Vref2 so that the frequency of the frequency-divided signal outputted from the frequency divider section 6 becomes equal to the target frequency fvco2. Then, the frequency characteristic G2 changes to G2′(dotted line), whereby the overall characteristic G10′ changes to G10″ (two-dot chain line). Therefore, the frequency of G10″ for the control voltage V2 is fvco2.

Thus, if the operating reference voltage control section 9 adjusts the operating reference voltages Vref1 to Vref3 to be outputted so that target frequencies for the control voltages V1 to V3 are satisfied, and then a PLL operation is performed while holding the operating reference voltages Vref1 to Vref3, it is possible to not only set the oscillation frequency to a desirable value but also set the control sensitivity with varied control voltage inputted to the VCO 5 to a desirable value.

Referring to FIG. 3B, if the control voltage V2 is set so that the frequency at the control voltage V1 is not influenced by the change from the frequency characteristic G2 to G2′ occurring due to the adjustment of the operating reference voltage Vref2, the frequency fvco1 at the control voltage V1, which has once been adjusted for the change from the overall characteristic G10 to G10′, does not need to be re-adjusted for the change from the overall characteristic G10′ to G10″.

If it is necessary, based on the result of the comparison by the frequency detection section 8, to adjust the operating reference voltage Vref2 by making a change by a certain value or more from the initial state, the value of the operating reference voltage Vref1 can be corrected according to the comparison result. Then, even where the frequency at the control voltage V1 would be influenced by the change from the frequency characteristic G2 to G2′ if correction were not performed, the frequency fvco1 at the control voltage V1, which has once been adjusted for the change from the overall characteristic G10 to G10′, can be held for the change from the overall characteristic G10′ to G10′.

As described above, according to the first embodiment of the present invention, it is possible to realize a frequency synthesizer, in which the control sensitivity is not influenced by variations in the production process, temperature variations, variations in the power supply voltage, or the like, while ensuring the frequency correction function in the prior art as proposed in Patent Document 2, and the like.

While the operation of the frequency synthesizer is turned ON/OFF based on the serial input signal in the first embodiment, a parallel input signal may be used in other embodiments.

While there are three operating reference voltages of Vref1 to Vref3 to be switched from one another by the control voltage switching section 7, the number of the operating reference voltages can be optimally selected to be any number greater than or equal to two depending on the required linearity of the frequency characteristic. For example, if there are provided two operating reference voltages Vref1 and Vref2 corresponding to the upper limit value and the lower limit value of the frequency characteristic, the configuration and the control will be easier but it is not possible to correct the non-linearity between the operating reference voltages Vref1 and Vref2. The more operating reference voltages there are provided, the finer it is possible to correct the non-linearity between the operating reference voltages Vref1 and Vref2, but with the configuration and the control being more complicated.

### Second Embodiment

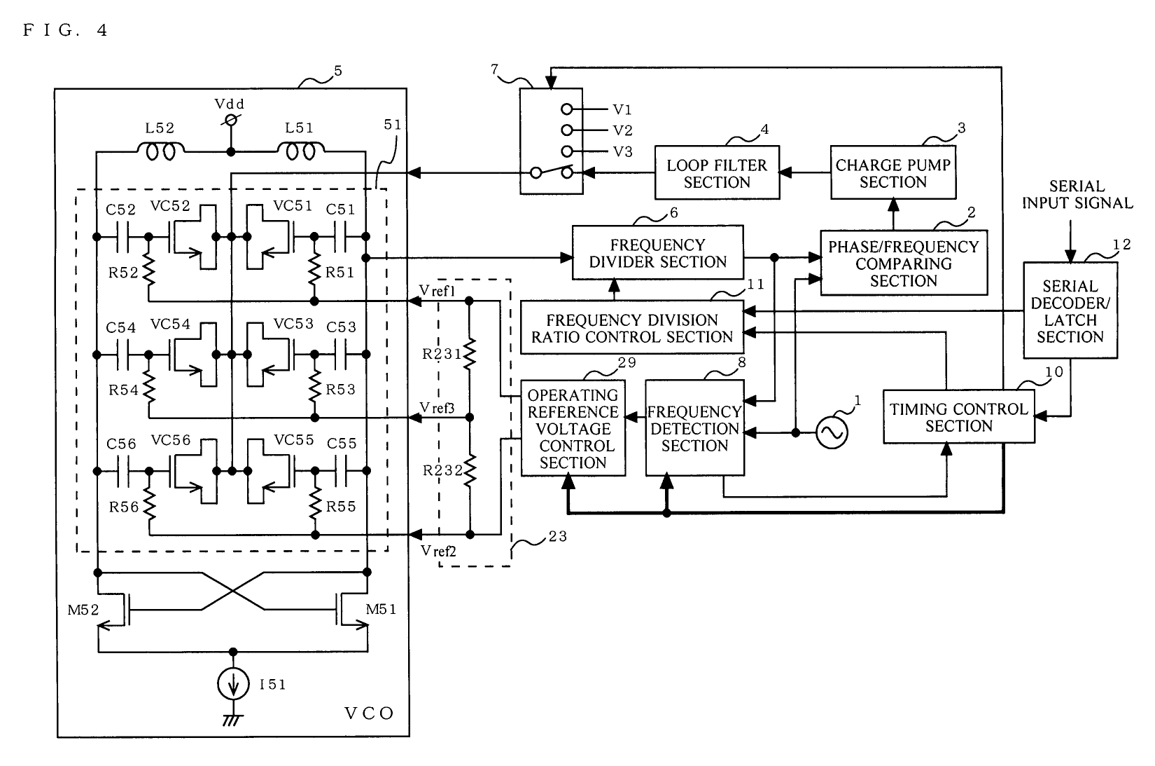

FIG. 4 shows a circuit configuration of a frequency synthesizer according to a second embodiment of the present invention. Referring to FIG. 4, the frequency synthesizer of the second embodiment includes the reference signal generating section 1, the phase/frequency comparing section 2, the charge pump section 3, the loop filter section 4, the VCO 5, the frequency divider section 6, the control voltage switching section 7, the frequency detection section 8, an operating reference voltage control section 29, the timing control section 10, the frequency division ratio control section 11, the serial decoder/latch section 12, and a voltage difference dividing section 23.

As can be seen from FIG. 4, the frequency synthesizer of the second embodiment differs from the frequency synthesizer of the first embodiment in the configuration of the operating reference voltage control section 29 and the voltage difference dividing section 23. Other elements of the frequency synthesizer of the second embodiment are the same as those of the frequency synthesizer of the first embodiment, and will be denoted by like reference numerals and not be further discussed below.

The operating reference voltage control section 29 receives an error signal produced by the frequency detection section 8 to output the operating reference voltage Vref1 for the variable capacitor elements VC51 and VC52 and the operating reference voltage Vref2 for the variable capacitor elements VC55 and VC56. The voltage difference dividing section 23 includes resistors R231 and R232 connected in series with each other, with one end of the resistor R231 connected to the operating reference voltage Vref1 and one end of the resistor R232 connected to the operating reference voltage Vref2. The connecting point between the other end of the resistor R231 and the other end of the resistor R232 is connected to the bias resistors R53 and R54 of the variable capacitor section 51, and the divided voltage appearing at the connecting point is supplied to the variable capacitor elements VC53 and VC54 as the operating reference voltage Vref3.

The operating reference voltage Vref3 is obtained from Expression 1 below:
Vref3=(R232×Vref1+R231×Vref2)/(R231+R232) Exp. 1
Particularly, if the value of the resistor R231 is equal to that of the resistor R232, Expression 2 below holds.
Vref3=(Vref1+Vref2)/2 Exp. 2

If the operating reference voltages Vref1 and Vref2 are used for setting the maximum value and the minimum value of the operating reference voltage to be given to the variable capacitor elements VC51 to VC56, the change in the operating reference voltage Vref3 can be linked with the change in the operating reference voltages Vref1 and Vref2.

As described above, with the frequency synthesizer according to the second embodiment of the present invention, the operating reference voltage control section 29 needs to output only two outputs, i.e., the operating reference voltages Vref1 and Vref2. Thus, it is possible with a simple configuration to set the control sensitivity with varied control voltage to the VCO 5 to a desirable value.

A capacitor may be inserted between the ground and the connecting point between the other end of the resistor R231 and the other end of the resistor R232 for the purpose of noise reduction. While the operating reference voltage control section 29 and the voltage difference dividing section 23 are treated as separate sections in the present embodiment, they may be combined together as an operating reference voltage control section.

### Third Embodiment

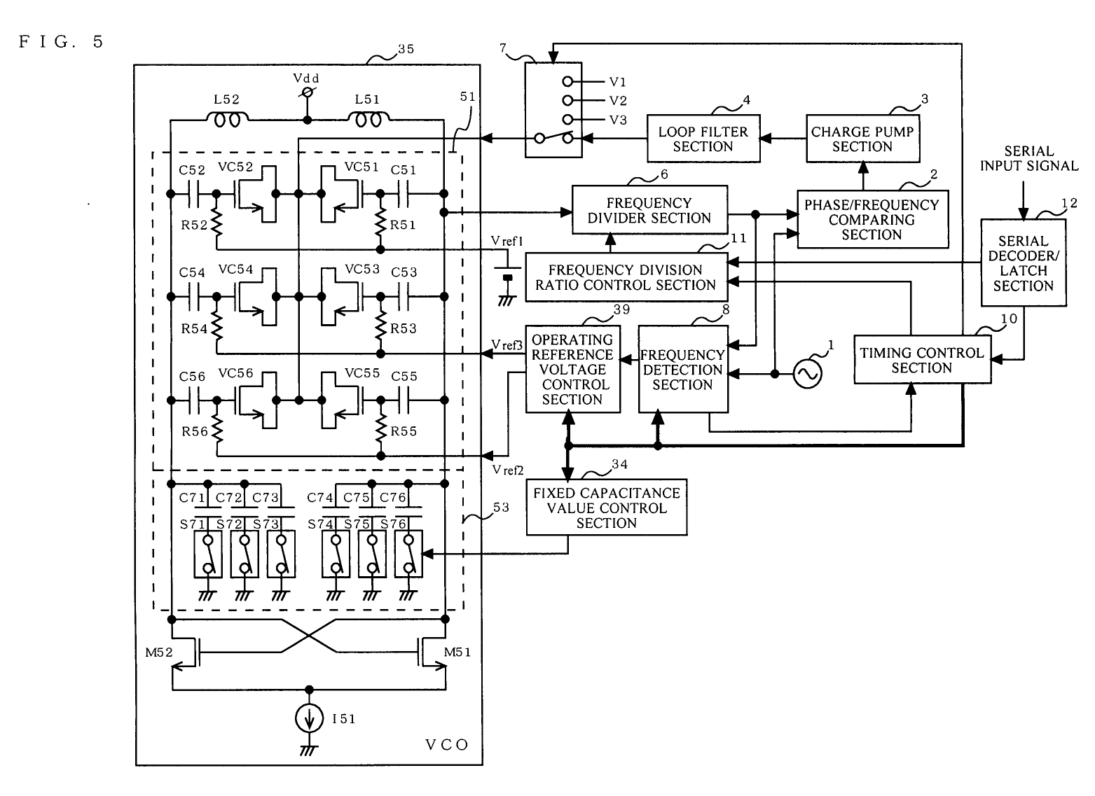

FIG. 5 shows a circuit configuration of a frequency synthesizer according to a third embodiment of the present invention. Referring to FIG. 5, the frequency synthesizer of the third embodiment includes the reference signal generating section 1, the phase/frequency comparing section 2, the charge pump section 3, the loop filter section 4, a VCO 35, the frequency divider section 6, the control voltage switching section 7, the frequency detection section 8, an operating reference voltage control section 39, the timing control section 10, the frequency division ratio control section 11, the serial decoder/latch section 12, and a fixed capacitance value control section 34. The VCO 35 includes the inductors L51 and L52, the variable capacitor section 51, a fixed capacitance value switching section 53, the transistors M51 and M52, and the current source I51.

As can be seen from FIG. 5, the frequency synthesizer of the third embodiment differs from the frequency synthesizer of the first embodiment in the configuration of the operating reference voltage control section 39, the fixed capacitance value control section 34 and the fixed capacitance value switching section 53. Other elements of the frequency synthesizer of the third embodiment are the same as those of the frequency synthesizer of the first embodiment, and will be denoted by like reference numerals and not be further discussed below.

The operating reference voltage control section 39 receives an error signal produced by the frequency detection section 8 to output the operating reference voltage Vref3 for the variable capacitor elements VC53 and VC54 and the operating reference voltage Vref2 for the variable capacitor elements VC55 and VC56. The operating reference voltage Vref1 is a fixed value. The fixed capacitance value switching section 53 includes capacitors C71 to C76 and switches S71 to S76, and turns ON/OFF the switches S71 to S76 based on the control signal from the fixed capacitance value control section 34. The oscillation frequency of the VCO 35 is determined by the inductors L51 and L52 and the capacitance component parallel to the inductors L51 and L52. Thus, when the switches S71 to S76 are ON, the capacitors C71 to C76 are connected together to contribute to the oscillation frequency, whereas when the switches S71 to S76 are OFF, there is very little effective capacitance value that contributes to the oscillation frequency.

The operation of the frequency synthesizer of the third embodiment having such a configuration will now be described.

The frequency synthesizer of the third embodiment is characteristic in that first, when the control voltage V1 is being selected, the effective capacitance value of the fixed capacitance value switching section 53 is varied by the fixed capacitance value control section 34 so that the frequency of the frequency-divided signal outputted from the frequency divider section 6 becomes equal to the target frequency fvco1. Then, the operating reference voltages Vref2 and Vref3 outputted from the operating reference voltage control section 39 are adjusted so that the target frequencies fvco2 and fvco3 corresponding to the control voltages V2 and V3 are satisfied. With this operation, if a PLL operation is performed while holding the adjusted operating reference voltages Vref2 and Vref3, it is possible to not only set the oscillation frequency to a desirable value but also set the control sensitivity with varied control voltage inputted to the VCO 35 to a desirable value, as in the first and second embodiments.

Consider a case where a serial input signal for transitioning the frequency synthesizer from OFF to ON is given to the serial decoder/latch section 12.

First, the timing control section 10 is notified by the serial decoder/latch section 12 of the information to turn ON the operation of the frequency synthesizer. In response to the notification, the timing control section 10 controls the control voltage switching section 7 so that the control voltage V1 is inputted to the VCO 35. The frequency divider section 6 is controlled by the frequency division ratio control section 11 so that the frequency division ratio becomes M1=fvco1/fref. The frequency detection section 8 compares the frequency of the frequency-divided signal outputted from the frequency divider section 6 with that of the reference signal outputted from the reference signal generating section 1, and changes the effective capacitance value of the fixed capacitance value switching section 53 so that the frequency of the frequency-divided signal outputted from the frequency divider section 6 becomes fvco/M1=fref. The subsequent operation of obtaining the operating reference voltages Vref2 and Vref3 when the control voltages V2 and V3 are inputted to the VCO 35 is as described above in the first embodiment.

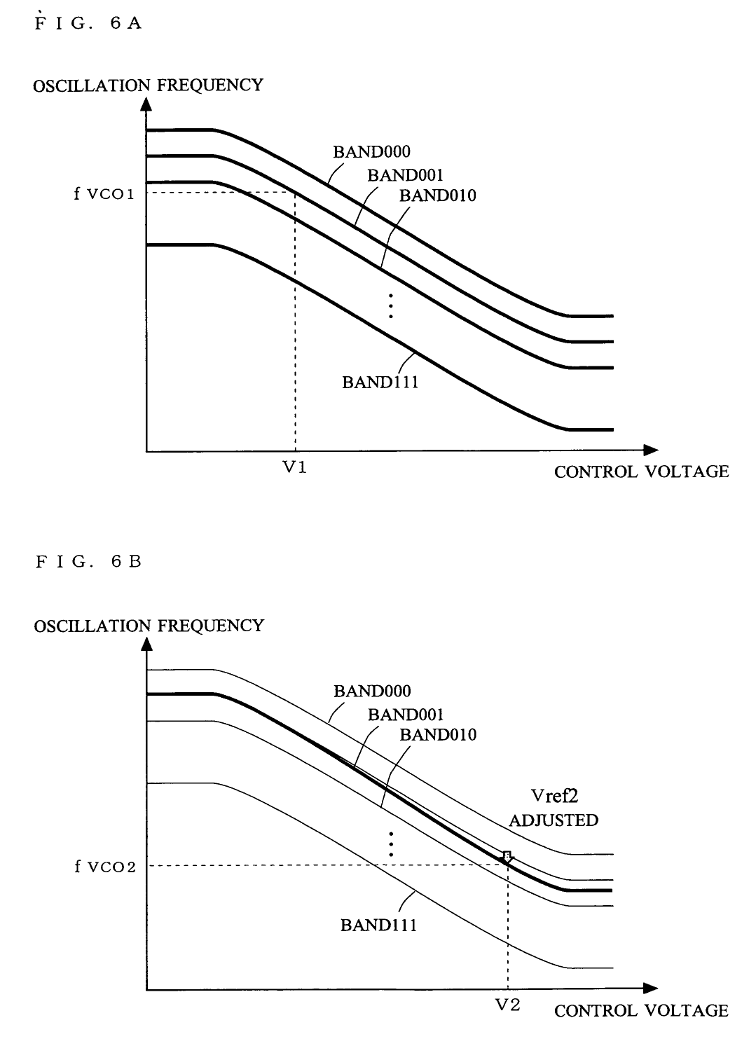

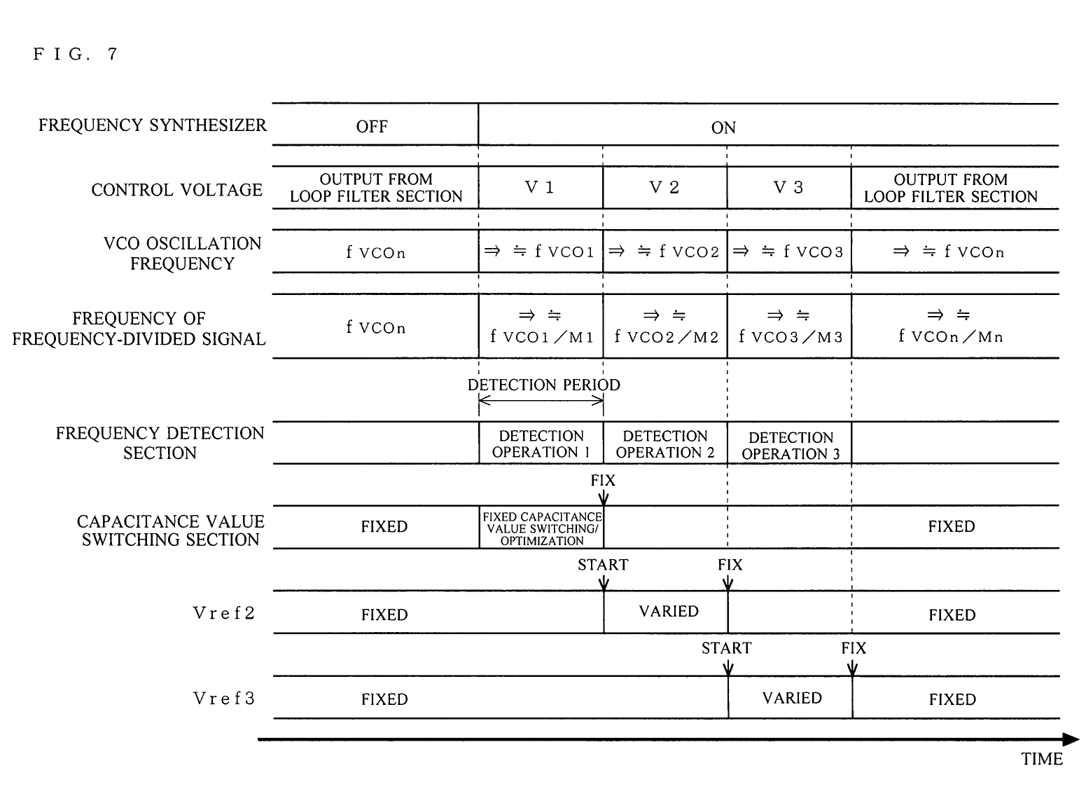

Referring to FIG. 6A, a method for adjusting the effective capacitance value of the fixed capacitance value switching section 53 will be described. FIGS. 6A and 6B show control voltage-oscillation frequency characteristic of the VCO 35. As shown in FIG. 5, the effective capacitance value of the fixed capacitance value switching section 53 is controlled in 3-bit control by the fixed capacitance value control section 34, and the frequency variation characteristics for the control voltages V1 to V3 can be represented by BAND000 to BAND111, respectively, as shown in FIG. 6A. Specifically, an optimal variation characteristic is selected so that the target value of the oscillation frequency fvco of the VCO 35 for the control voltage V1 becomes equal to fvco1. In the example of FIG. 6A, where BAND001 is the optimal value, the effective capacitance value of the fixed capacitance value switching section 53 is fixed at BAND001, and the detection process ends. FIG. 7 is a timing diagram showing an operation example of the frequency synthesizer of the third embodiment.

As described above, with the frequency synthesizer according to the third embodiment of the present invention, the target frequency fvco1 is set for the control voltage V1 by adjusting the effective capacitance value of the fixed capacitance value switching section 53 included in the VCO 35, but not by adjusting the operating reference voltage Vref. Thus, it is possible to set the control sensitivity with varied control voltage to the VCO 35 to a desirable value.

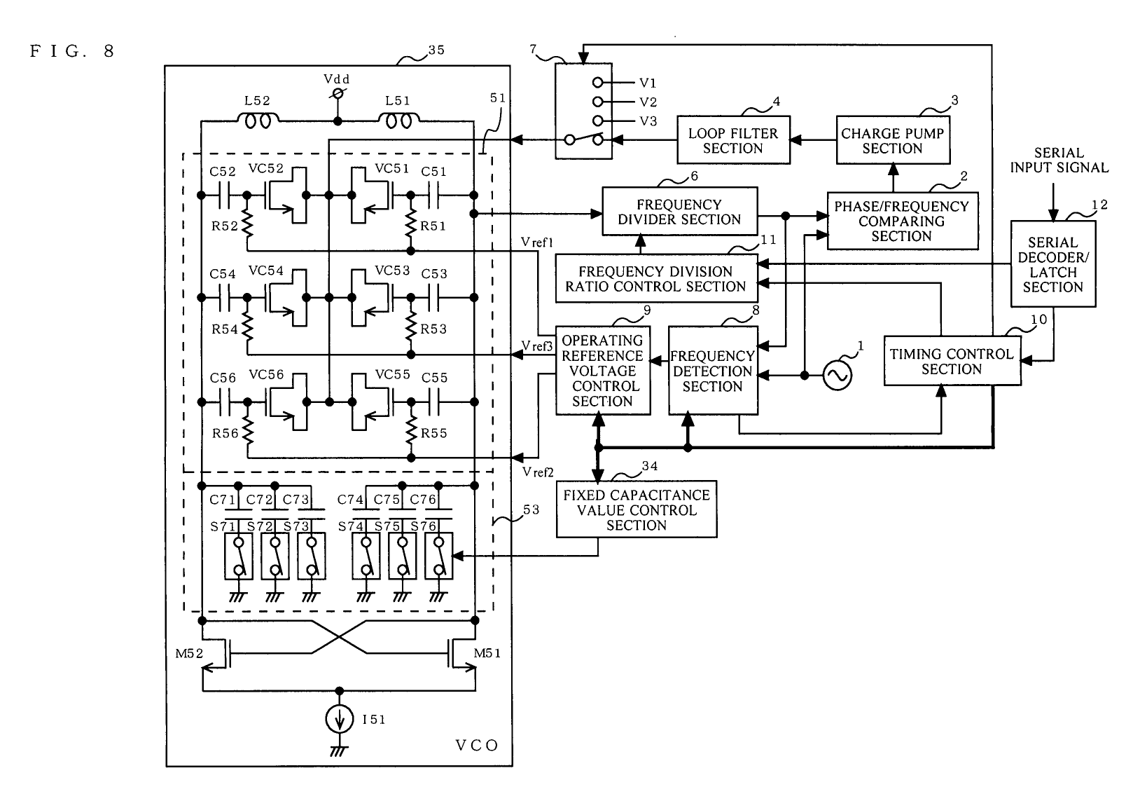

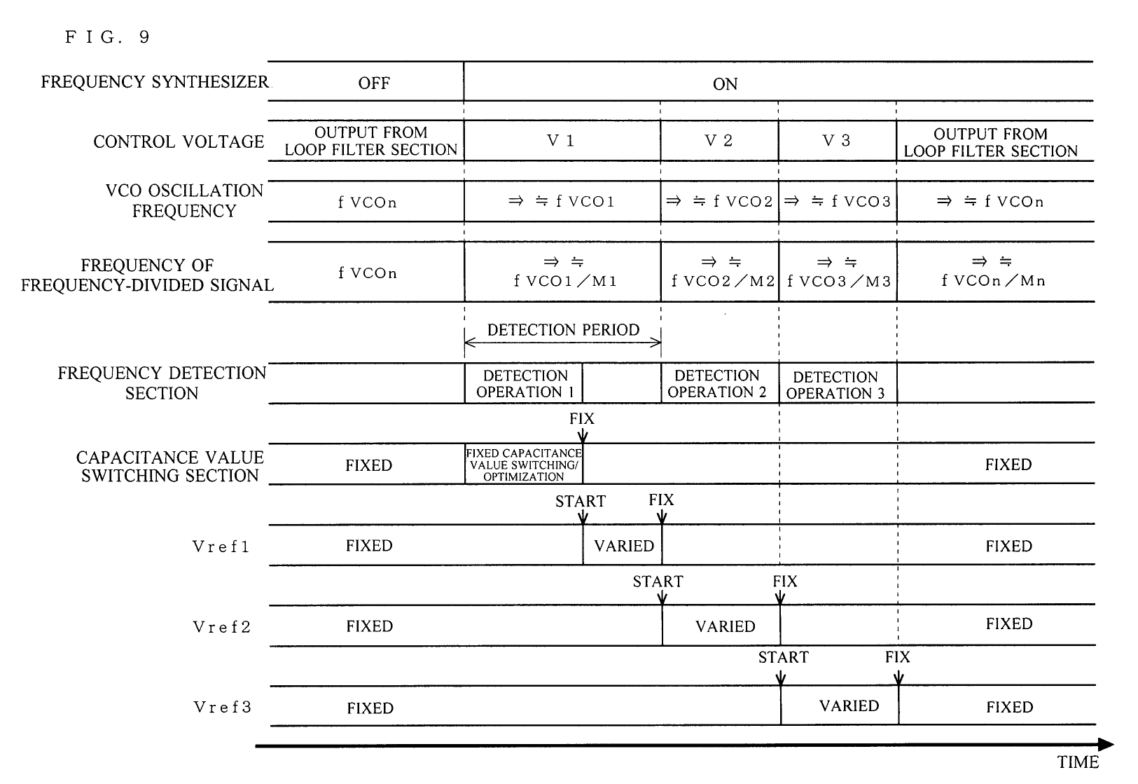

In the third embodiment, the target frequency fvco1 for the control voltage V1 is adjusted by changing the effective capacitance value of the fixed capacitance value switching section 53, thus eliminating the need to adjust the operating reference voltage Vref1. In a case where the number of bits is small and the effective capacitance value of the fixed capacitance value switching section 53 changes by a large amount in each BAND, the target frequency fvco1 for the control voltage V1 may be adjusted by first coarsely adjusting it with the fixed capacitance value control section 34 and then finely adjusting it with the operating reference voltage Vref1. In such a case, the frequency synthesizer will have a circuit configuration as shown in FIG. 8 and operate as shown in FIG. 9.

### Fourth Embodiment

FIG. 10 shows a circuit configuration of a frequency synthesizer according to a fourth embodiment of the present invention. Referring to FIG. 10, the frequency synthesizer of the fourth embodiment includes the reference signal generating section 1, a modulation signal producing section 41, the phase/frequency comparing section 2, the charge pump section 3, the loop filter section 4, a VCO 45, the frequency divider section 6, a first control voltage switching section 7, a second control voltage switching section 47, the frequency detection section 8, the operating reference voltage control section 9, the timing control section 10, the frequency division ratio control section 11, the serial decoder/latch section 12, and the fixed capacitance value control section 34. The VCO 45 includes the inductors L51 and L52, a first variable capacitor section 51, a second variable capacitor section 52, the fixed capacitance value switching section 53, the transistors M51 and M52, and the current source I51.

As can be seen from FIG. 10, the frequency synthesizer of the fourth embodiment differs from the frequency synthesizer of the first embodiment in the configuration of the modulation signal producing section 41, the second control voltage switching section 47, the fixed capacitance value control section 34, the second variable capacitor section 52 and the fixed capacitance value switching section 53. Other elements of the frequency synthesizer of the fourth embodiment are the same as those of the frequency synthesizer of the first or third embodiment, and will be denoted by like reference numerals and not be further discussed below.

The second variable capacitor section 52 includes variable capacitor elements VC61 to VC66 whose capacitance values vary according to the voltage applied between opposite ends thereof, capacitors C61 to C66 connected to one end of the variable capacitor elements VC61 to VC66 for blocking the direct current component, and bias resistors R61 to R66 for transmitting the operating reference voltages for the variable capacitor elements VC61 to VC66. The operating reference voltage control section 9 receives an error signal produced by the frequency detection section 8 to output the operating reference voltage Vref11 for the variable capacitor elements VC61 and VC62, the operating reference voltage Vref12 for the variable capacitor elements VC65 and VC66, and the operating reference voltage Vref13 for the variable capacitor elements VC63 and VC64. The control voltage switching section 7 receives the voltage outputted from the loop filter section 4 and a control voltage (V1 in the example shown in FIG. 10), and selectively outputs one of the input voltages as the first control voltage to the first variable capacitor section 51 of the VCO 45. The modulation signal producing section 41 produces a predetermined modulation signal. The second control voltage switching section 47 receives the modulation signal produced by the modulation signal producing section 41 and a plurality of control voltages (V11 to V13 in the example shown in FIG. 10), and selectively outputs one of the input voltages as the second control voltage to the second variable capacitor section 52 of the VCO 45. The operating reference voltages Vref1 to Vref3 are fixed values.

The operation of the frequency synthesizer of the fourth embodiment having such a configuration will now be described.

Consider a case where a serial input signal for transitioning the frequency synthesizer from OFF to ON is given to the serial decoder/latch section 12. The timing control section 10 controls the control voltage switching section 7 so that the first control voltage V1 is inputted to the first variable capacitor section 51 of the VCO 45, and controls the second control voltage switching section 47 so that the second control voltage V11 is inputted to the second variable capacitor section 52 of the VCO 45. Where fvco1 is the target value of the oscillation frequency fvco of the VCO 45 when the first control voltage V1 and the second control voltage V11 are inputted, the frequency divider section 6 is controlled by the frequency division ratio control section 11 so that the frequency division ratio M1 becomes M1=fvco1/fref. The frequency detection section 8 compares the frequency of the frequency-divided signal outputted from the frequency divider section 6 with that of the reference signal outputted from the reference signal generating section 1, and changes the operating reference voltage Vref11 of the VCO 45 so that the frequency of the frequency-divided signal outputted from the frequency divider section 6 becomes fvco/M1=fref, i.e., so that the frequency of the VCO 45 becomes fvco=fref×M1=fvco1.

When the frequency of the VCO 45 becomes equal to the target value fvco1, the operating reference voltage Vref11 at that time is fixed, and the timing control section 10 next controls the second control voltage switching section 47 so that the second control voltage V12 is inputted to the second variable capacitor section 52 of the VCO 45. Where fvco12 is the target value of the oscillation frequency fvco of the VCO 45 when the second control voltage V12 is inputted, the frequency divider section 6 is controlled by the frequency division ratio control section 11 so that the frequency division ratio M12 becomes M12=fvco12/fref. The frequency detection section 8 compares the frequency of the frequency-divided signal outputted from the frequency divider section 6 with that of the reference signal outputted from the reference signal generating section 1, and changes the operating reference voltage Vref12 of the VCO 45 so that the frequency of the frequency-divided signal outputted from the frequency divider section 6 becomes fvco/M12=fref, i.e., so that the frequency of the VCO 45 becomes fvco=fref×M12=fvco12.

When the frequency of the VCO 45 becomes equal to the target value fvco12, the operating reference voltage Vref12 at that time is fixed, and the timing control section 10 next controls the second control voltage switching section 47 so that the second control voltage V13 is inputted to the second variable capacitor section 52 of the VCO 45. Where fvco13 is the target value of the oscillation frequency fvco of the VCO 45 when the second control voltage V13 is inputted, the frequency divider section 6 is controlled by the frequency division ratio control section 11 so that the frequency division ratio M13 becomes M13=fvco13/fref. The frequency detection section 8 compares the frequency of the frequency-divided signal outputted from the frequency divider section 6 with that of the reference signal outputted from the reference signal generating section 1, and changes the operating reference voltage Vref13 of the VCO 45 so that the frequency of the frequency-divided signal outputted from the frequency divider section 6 becomes fvco/M13=fref, i.e., so that the frequency of the VCO 45 becomes fvco=fref×M13=fvco13.

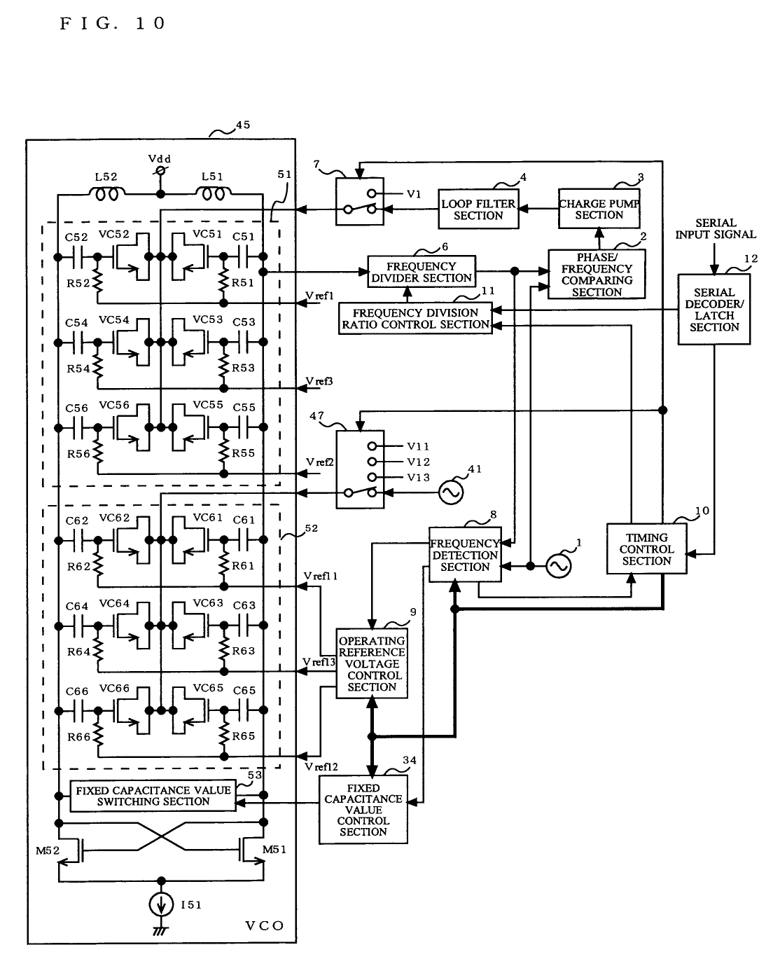

FIG. 11 is a timing diagram showing an operation example of the frequency synthesizer of the fourth embodiment.

As described above, according to the fourth embodiment of the present invention, it is possible to realize a frequency synthesizer, in which the control sensitivity and the modulation sensitivity are not influenced by variations in the production process, temperature variations, variations in the power supply voltage, or the like, while ensuring the frequency correction function in the prior art as proposed in Patent Document 2, and the like.

While the fourth embodiment is directed to a configuration where the oscillation frequency (sensitivity) with respect to the first control voltage V1 of the first variable capacitor section 51 is not adjusted, the first control voltages V1 to V3 may be applied one by one to the VCO 45 to obtain the operating reference voltages Vref1 to Vref3, respectively, as described above in the first embodiment. In such a case, the operating reference voltages Vref11 to Vref13 can be adjusted after the operating reference voltages Vref1 to Vref3 are adjusted, whereby both operating reference voltages can be appropriately adjusted to desirable values.

The fixed capacitance value control section 34 and the fixed capacitance value switching section 53 are not necessary components. The operating reference voltage Vref13 may be a divided voltage obtained by resistance division between the operating reference voltage Vref11 and the operating reference voltage Vref12.

The first to fourth embodiments are each directed to a configuration where the first variable capacitor section 51 or the second variable capacitor section 52 in the VCO 5, 35 or 45 includes three pairs of variable capacitor elements VC51-VC52, VC53-VC54 and VC55-VC56, or VC61-VC62, VC63-VC64 and VC65-VC66. The number of pairs is not limited to three, but may be two, four or more depending on the desired frequency characteristic.

### EXAMPLE 1 OF WIRELESS COMMUNICATIONS DEVICE

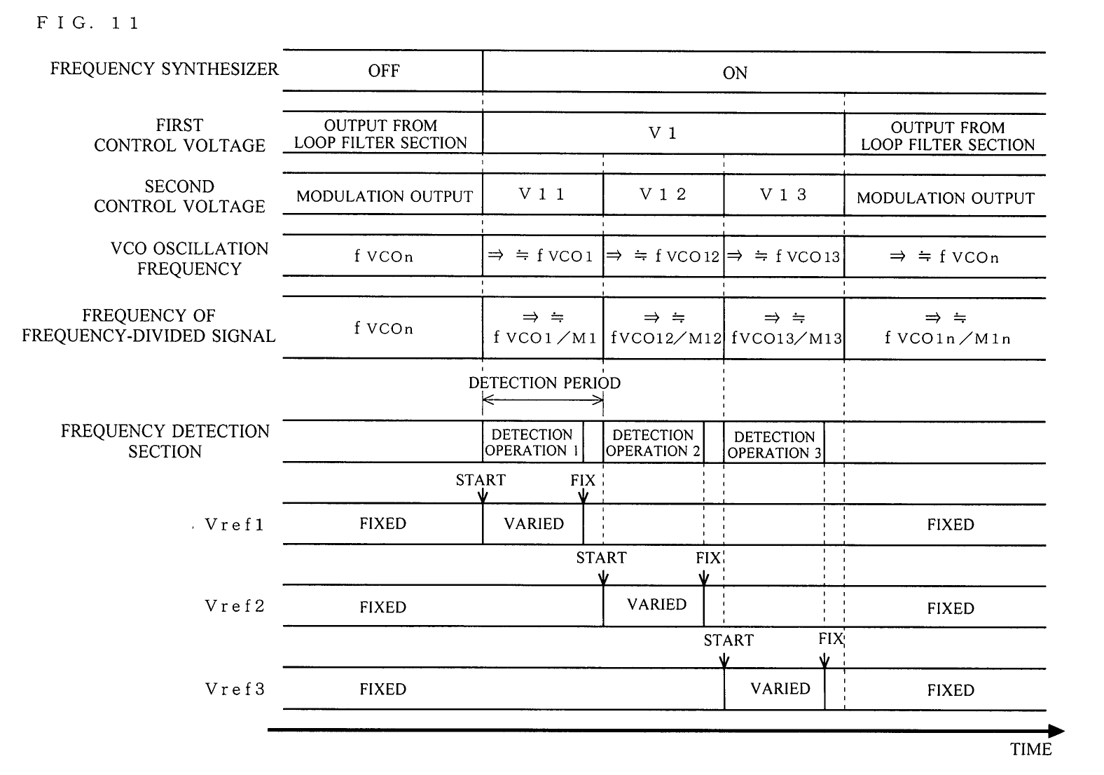

FIG. 12 shows an exemplary circuit configuration of a wireless communications device 100 using a frequency synthesizer according to the first to fourth embodiments of the present invention. Referring to FIG. 12, the wireless communications device 100 includes an antenna 120, an amplification circuit 101, a frequency conversion circuit 102, and a frequency synthesizer 103. Thus, the wireless communications device 100 forms a receiver circuit.

An RF signal (radio frequency signal) received by the antenna 120 is amplified through the amplification circuit 101. The frequency synthesizer 103 is one of the frequency synthesizers of the first to fourth embodiments, and produces a local oscillation signal. Using the local oscillation signal produced by the frequency synthesizer 103, the frequency conversion circuit 102 converts the RF signal, which has been amplified through the amplification circuit 101, to a receive baseband signal. With the frequency synthesizer 103, not only the oscillation frequency of the frequency synthesizer 103 is set to a desirable value but also the control sensitivity is set to a desirable value. Therefore, the wireless communications device 100 is a device in which the control sensitivity and the modulation sensitivity of the frequency synthesizer 103 are not influenced by variations in the production process, temperature variations, variations in the power supply voltage, or the like.

### EXAMPLE 2 OF WIRELESS COMMUNICATIONS DEVICE

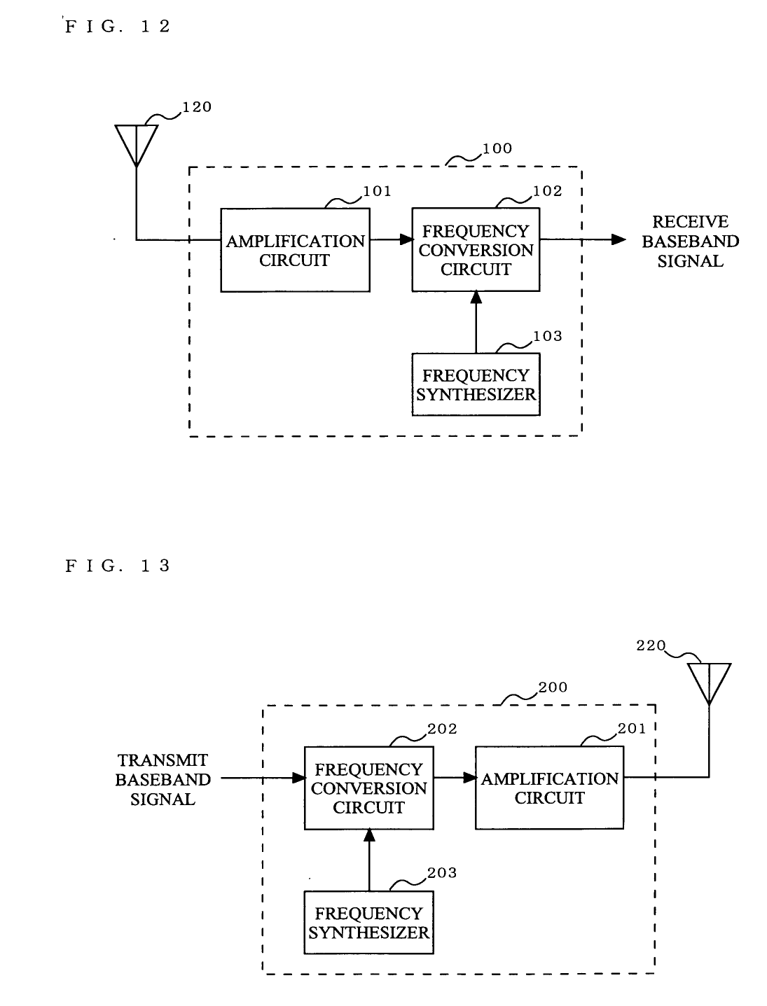

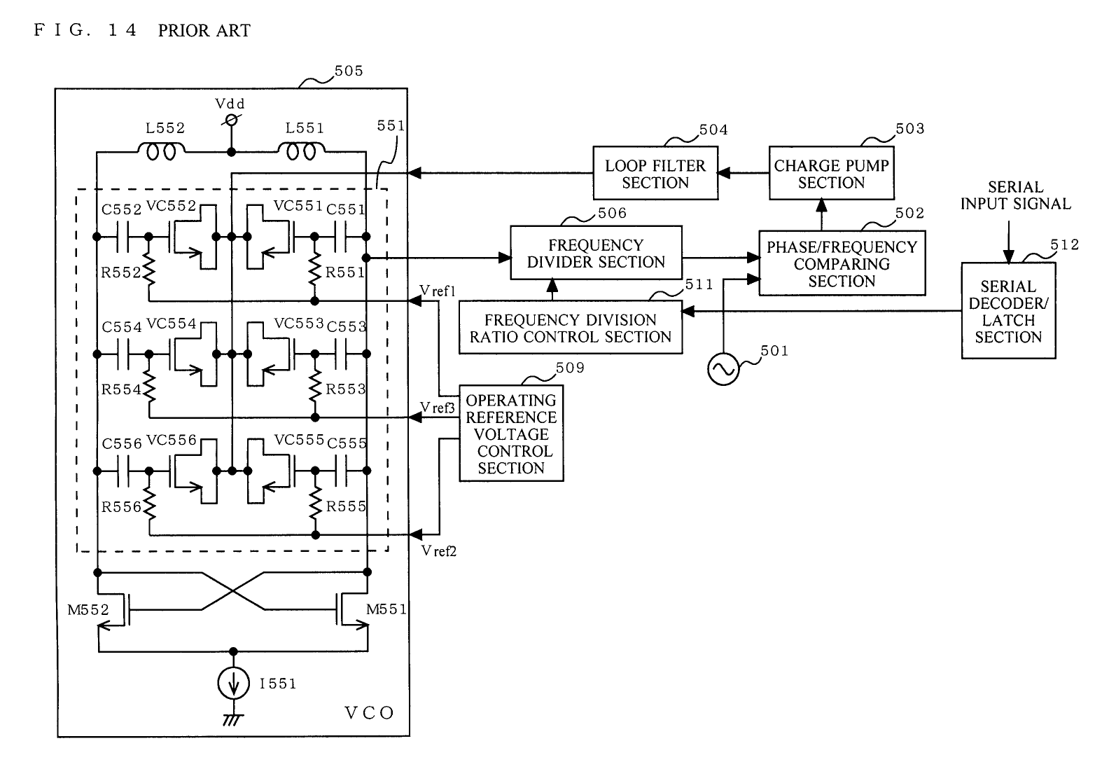

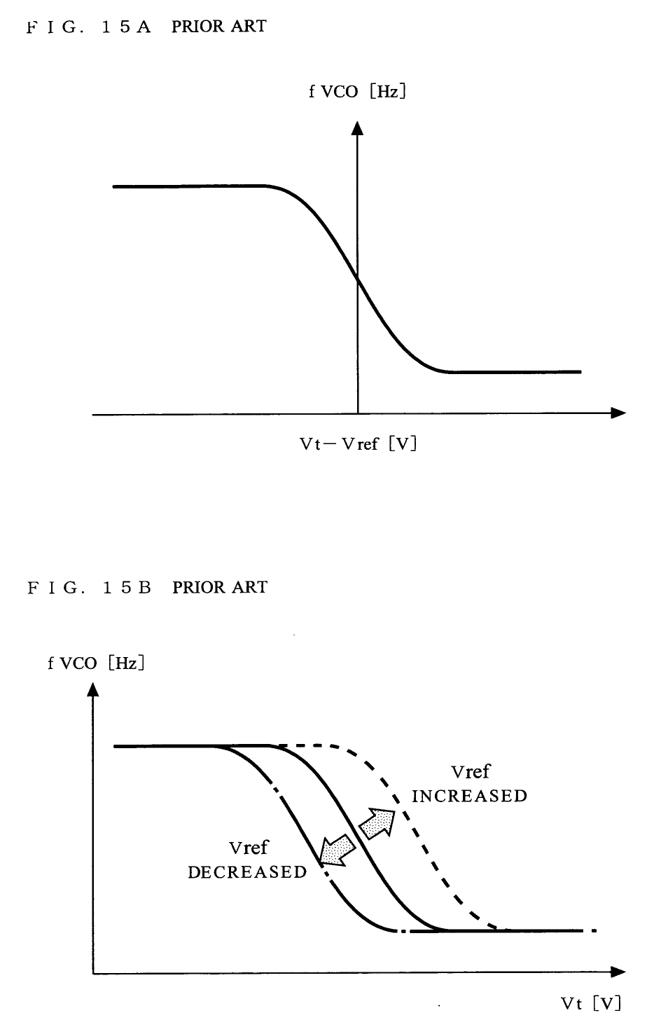

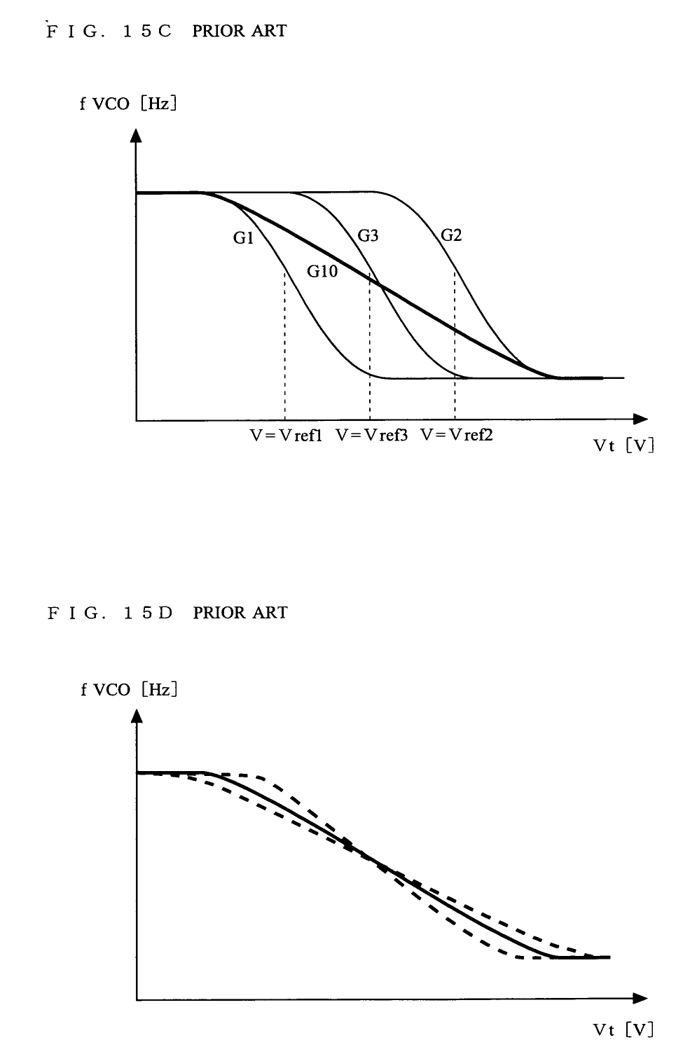

FIG. 13 shows an exemplary circuit configuration of a wireless communications device 200 using a frequency synthesizer according to the first to fourth embodiments of the present invention. Referring to FIG. 13, the wireless communications device 200 includes an antenna 220, an amplification circuit 201, a frequency conversion circuit 202, and a frequency synthesizer 203. Thus, the wireless communications device 200 forms a transmitter circuit.

The frequency synthesizer 203 is one of the frequency synthesizers of the first to fourth embodiments, and produces a local oscillation signal. Using the local oscillation signal produced by the frequency synthesizer 203, the frequency conversion circuit 202 converts the received transmit baseband signal to an RF signal. The amplification circuit 201 amplifies the RF signal and transmits the amplified signal from the antenna 220. With the frequency synthesizer 203, not only the oscillation frequency of the frequency synthesizer 203 is set to a desirable value but also the control sensitivity is set to a desirable value. Therefore, the wireless communications device 200 is a device in which the control sensitivity and the modulation sensitivity of the frequency synthesizer 203 are not influenced by variations in the production process, temperature variations, variations in the power supply voltage, or the like.

While the invention has been described in detail, the foregoing description is in all aspects illustrative and not restrictive. It is understood that numerous other modifications and variations can be devised without departing from the scope of the invention.

What is claimed is:

1. A frequency synthesizer for use in a semiconductor integrated circuit, the frequency synthesizer comprising:
a voltage controlled oscillator section, including a variable capacitor section including a plurality of variable capacitor elements whose capacitance values vary according to a control voltage applied between opposite ends thereof, for outputting a signal of an oscillation frequency based on the control voltage and a plurality of predetermined operating reference voltages;
a frequency divider section for dividing a frequency of a signal outputted from the voltage controlled oscillator section with a predetermined frequency division ratio;
a voltage producing section for comparing the frequency-divided signal from the frequency divider section with a predetermined reference signal, and producing a voltage for performing a feedback control of an oscillation frequency of the voltage controlled oscillator section based on a result of the comparison;
a control voltage switching section for receiving the voltage produced by the voltage producing section and a plurality of fixed voltages of different values, and selectively outputting one of the received voltages to the voltage controlled oscillator section as the control voltage;
a frequency detection section for comparing a frequency of the frequency-divided signal from the frequency divider section with the frequency of the predetermined reference signal, and producing an error signal based on a result of the comparison;
an operating reference voltage control section for varying each of a plurality of operating reference voltages to be supplied to the plurality of variable capacitor elements according to the error signal produced by the frequency detection section; and
a timing control section for specifying a voltage to be selected in the control voltage switching section, controlling switching operation timing of the control voltage switching section, controlling operation timing of the frequency detection section, specifying an operating reference voltage to be varied by the operating reference voltage control section, and controlling operation timing of the operating reference voltage control section.

2. The frequency synthesizer according to claim 1, wherein:
the operating reference voltage control section includes a plurality of resistors inserted in a serial arrangement between any two of the operating reference voltages; and
a voltage obtained through voltage division by means of the plurality of resistors is supplied to the plurality of variable capacitor elements as at least one of the operating reference voltages.

3. The frequency synthesizer according to claim 1, wherein:
the voltage controlled oscillator section includes a fixed capacitance value switching section for switching between capacitance values of the voltage controlled oscillator section by adding a fixed capacitance to the variable capacitor section; and
the frequency synthesizer further comprises a fixed capacitance value control section for controlling the fixed capacitance value added to the variable capacitor section by the fixed capacitance value switching section under a control by the timing control section.

4. The frequency synthesizer according to claim 2, wherein:
the voltage controlled oscillator section includes a fixed capacitance value switching section for switching between capacitance values of the voltage controlled oscillator section by adding a fixed capacitance to the variable capacitor section; and
the frequency synthesizer further comprises a fixed capacitance value control section for controlling the fixed capacitance value added to the variable capacitor section by the fixed capacitance value switching section under a control by the timing control section.

5. A frequency synthesizer for use in a semiconductor integrated circuit;
a voltage controlled oscillator section, including a first variable capacitor section including a plurality of variable capacitor elements whose capacitance values vary according to a first control voltage applied between opposite ends thereof and a second variable capacitor section including a plurality of variable capacitor elements whose capacitance values vary according to a second control voltage applied between opposite ends thereof, for outputting a signal of an oscillation frequency based on the first and second control voltages and a plurality of predetermined operating reference voltages;
a frequency divider section for dividing a frequency of a signal outputted from the first variable capacitor section of the voltage controlled oscillator section with a predetermined frequency division ratio;
a voltage producing section for comparing the frequency-divided signal from the frequency divider section with a predetermined reference signal, and producing a voltage for performing a feedback control of an oscillation frequency of the voltage controlled oscillator section based on a result of the comparison;
a first control voltage switching section for receiving the voltage produced by the voltage producing section and a fixed voltage, and selectively outputting one of the received voltages to the voltage controlled oscillator section as the first control voltage;
a second control voltage switching section for receiving a predetermined modulation signal voltage and a plurality of fixed voltages of different values, and selectively outputting one of the received voltages to the voltage controlled oscillator section as the second control voltage;
a frequency detection section for comparing a frequency of the frequency-divided signal from the frequency divider section with the frequency of the predetermined reference signal, and producing an error signal based on a result of the comparison;
an operating reference voltage control section for varying each of a plurality of operating reference voltages to be supplied to the plurality of variable capacitor elements of the second variable capacitor section according to the error signal produced by the frequency detection section; and
a timing control section for specifying a voltage to be selected in each of the first and second control voltage switching sections, controlling switching operation timing of each of the first and second control voltage switching sections, controlling operation timing of the frequency detection section, specifying an operating reference voltage varied in the operating reference voltage control section, and controlling operation timing of the operating reference voltage control section.

6. The frequency synthesizer according to claim 5, wherein:
the operating reference voltage control section includes a plurality of resistors inserted in a serial arrangement between any two of the operating reference voltages; and
a voltage obtained through voltage division by means of the plurality of resistors is supplied to the plurality of variable capacitor elements as at least one of the operating reference voltages.

7. The frequency synthesizer according to claim 5, wherein:
the voltage controlled oscillator section includes a fixed capacitance value switching section for switching between capacitance values of the voltage controlled oscillator section by adding a fixed capacitance to the variable capacitor section; and
the frequency synthesizer further comprises a fixed capacitance value control section for controlling the fixed capacitance value added to the variable capacitor section by the fixed capacitance value switching section under a control by the timing control section.

8. The frequency synthesizer according to claim 6, wherein:
the voltage controlled oscillator section includes a fixed capacitance value switching section for switching between capacitance values of the voltage controlled oscillator section by adding a fixed capacitance to the variable capacitor section; and
the frequency synthesizer further comprises a fixed capacitance value control section for controlling the fixed capacitance value added to the variable capacitor section by the fixed capacitance value switching section under a control by the timing control section.

9. A wireless communications device, comprising a receiver circuit including the frequency synthesizer according to claim 1, and a receiver antenna.

10. A wireless communications device, comprising a receiver circuit including the frequency synthesizer according to claim 5, and a receiver antenna.

11. A wireless communications device, comprising a transmitter circuit including the frequency synthesizer according to claim 1, and a transmitter antenna.

12. A wireless communications device, comprising a transmitter circuit including the frequency synthesizer according to claim 5, and a transmitter antenna.

13. A method for controlling an output signal of a frequency synthesizer by controlling a control voltage and an operating reference voltage to be supplied to a variable capacitor element whose capacitance value varies according to a voltage, the method comprising the steps of:
applying one of a plurality of control voltages of different values to the variable capacitor element, the applied control voltage being selected sequentially in a predetermined order from among the plurality of control voltages;
adjusting, for a first control voltage of the plurality of control voltages, a corresponding operating reference voltage so that a frequency of the output signal of the frequency synthesizer becomes equal to a first target frequency predetermined for the first control voltage;
adjusting, for at least one of a plurality of control voltages other than the first control voltage after adjusting the operating reference voltage for the first control voltage, a corresponding operating reference voltage so that the frequency of the output signal of the frequency synthesizer becomes equal to a target frequency predetermined for the at least one control voltage; and
performing, after adjusting the operating reference voltage for the at least one control voltage, a PLL operation while holding all of the adjusted operating reference voltages.

14. The method according to claim 13, further comprising the steps of:
setting the control voltage to a first value and detecting a frequency of the output signal of the frequency synthesizer at that point in time as a first frequency;
varying a first operating reference voltage so that a desired frequency is obtained;
setting the control voltage to a second value after adjusting the first operating reference voltage and detecting a frequency of the output signal of the frequency synthesizer at that point in time as a second frequency;
varying a second operating reference voltage so that a desired frequency is obtained; and
adjusting the first operating reference voltage to correct how the first frequency changes when the second operating reference voltage is varied.

15. A method for controlling an output signal of a frequency synthesizer by switching between fixed capacitance values and by controlling a control voltage and an operating reference voltage to be supplied to a variable capacitor element whose capacitance value varies according to a voltage, the method comprising the steps of:
applying one of a plurality of control voltages of different values to the variable capacitor element, the applied control voltage being selected sequentially in a predetermined order from among the plurality of control voltages;
adjusting, for a first control voltage of the plurality of control voltages, the switching between fixed capacitance values so that the frequency of the output signal of the frequency synthesizer becomes equal to a first target frequency predetermined for the first control voltage;
adjusting, for at least one of a plurality of control voltages other than the first control voltage after adjusting the switching between fixed capacitance values for the first control voltage, a corresponding operating reference voltage so that the frequency of the output signal of the frequency synthesizer becomes equal to a target frequency predetermined for the at least one control voltage; and
performing, after adjusting the operating reference voltage for the at least one control voltage, a PLL operation while holding all of the adjusted operating reference voltages.
